(19) United States
(12) Patent Application Publication
(10) Pub. No.: US 2020/0168753 A1
(43) Pub. Date: May 28, 2020

(54) PID-FREE ENCAPSULANT FOR PHOTOVOLTAIC MODULE, PHOTOVOLTAIC MODULE INCLUDING SAME, AND METHOD OF MANUFACTURING SAME

(71) Applicant: KOREA INSTITUTE OF ENERGY RESEARCH, Daejeon (KR)

(72) Inventors: Young-joo Eo, Daejeon (KR); Jihye Gwak, Daejeon (KR); Se-jin Ahn, Daejeon (KR); Ara Cho, Daejeon (KR); Jin-su Yoo, Daejeon (KR); Jun-sik Cho, Daejeon (KR); Seung-kyu Ahn, Daejeon (KR); Joo-hyung Park, Daejeon (KR); Kihwan Kim, Daejeon (KR); Donghyeop Shin, Daejeon (KR); Soo Min Song, Daejeon (KR); Inyoung Jeong, Daejeon (KR); Sang Min Lee, Daejeon (KR)

(21) Appl. No.: 16/747,532

(22) Filed: Jan. 21, 2020

(30) Foreign Application Priority Data
Nov. 26, 2018 (KR) 10-2018-0147592

(51) Int. Cl. H01L 31/048; H01L 31/18; C08F 210/02; C08F 216/06; C08K 3/36; C09K 3/10

(52) U.S. Cl. CPC H01L 31/0481; H01L 31/1876; C08F 210/02; C08F 216/06; C09K 2200/0247; C09K 3/10; C08K 2201/006; C09K 2200/0622; C08K 3/36

(57) ABSTRACT

The present invention relates to an encapsulant capable of reducing potential-induced degradation (PID). The encapsulant is used to seal a solar cell to form a photovoltaic module, in which silica gel is dispersed in the encapsulant as a sodium ion adsorbent. Since the silica gel that is highly transparent is used as the sodium ion adsorbent, it is possible to prevent PID attributable to sodium ions and to prevent deterioration in photovoltaic efficiency of the photovoltaic module. Since the silica gel has a high specific surface area, it is possible to adsorb sodium ions with a small amount of the silica gel.

### BACKGROUND OF THE INVENTION

### 1. Field of the Invention

The present invention relates to a photovoltaic module and an encapsulant used for the photovoltaic module. More particularly, the present invention relates to an encapsulant and a photovoltaic module capable of preventing a potential-induced degradation (PID) phenomenon.

### 2. Description of the Related Art

Solar cells that generate electricity using sunlight are usually used outdoors to absorb sunlight. Therefore, solar cells for photoelectric conversion and conductive wires for electricity transfer deteriorate over time, resulting in photovoltaic efficiency gradually decreasing. Due to this problem, solar cells are not used in the form of bare cells. That is, the bodies of solar cells are packaged with various protective materials. Solar cells wrapped with packaging are called photovoltaic modules, and a photovoltaic element provided in a photovoltaic module is referred to as a solar cell so as to be distinguished from the photovoltaic module.

Potential induced degradation (PID) is a phenomenon in which a leakage current generated due to a difference between the potential of the frame of a photovoltaic module and the potential of a solar cell provided in the photovoltaic module causes deterioration in the overall performance of the photovoltaic module. Two PID mechanisms are known. First, sodium ions contained in a glass plate used in a photovoltaic module diffuse into an encapsulant sheet (i.e., packaging), thereby increasing the conductivity of the encapsulant sheet, resulting in an increase in leakage current. Second, the sodium ions move to the surface of a solar cell and causes dielectric breakdown of an insulating film of the solar cell.

In order to solve the PID-related problem, Korea Patent Application Publication 10-2014-0090340 discloses a method of increasing the dielectric strength of EVA by refining additives used in an EVA encapsulant. In addition, Japanese Patent Application Publication No. 2014-150246 discloses a method of using an additive having a sodium ion adsorption function to suppress movement of sodium ions. In addition, Korean Patent No. 10-1860651 discloses a method of using an EVA sheet containing a variety of adsorbents for metal ions.

However, all these technologies have a disadvantage of lowering the photovoltaic efficiency of a photovoltaic module because the additives significantly reduce the light transmittance of the photovoltaic module.

### SUMMARY OF THE INVENTION

The present invention has been made to solve the problems occurring in the related art and an objective of the present invention is to provide an encapsulant capable of suppressing PID without lowering light transmittance and to provide a photovoltaic module using the encapsulant.

In order to accomplish the objective, according to one aspect of the present invention, there is provided a PID-free encapsulant for a photovoltaic module. The encapsulant which is a packaging material for a solar cell contains silica gel dispersed as a sodium ion adsorbent.

Silica gel is widely used as a hygroscopic agent due to its large specific surface area. Silica gel absorbs moisture by forming hydrogen bonds with water molecules on the surface thereof. Observing the phenomenon in which the water molecules are hydrogen-bonded to OH— present on the surface of silica gel, the inventors of the present invention have derived a method of adsorbing sodium ions which cause a PID phenomenon by adding silica gel to an encapsulant material. The inventors of the present invention also found that it was difficult to disperse silica gel in an encapsulant material. Therefore, the inventors have studied to solve the problem and come to the present invention by finding a method of improving the dispersibility of silica gel in an encapsulant material.

It is preferable that the surface area of the silica gel dispersed in the encapsulant is in a range of 500 m²/g to 800 m²/g and the silica gel is contained in an amount of 0.01 parts by weight to 1 part by weight based on 100 parts by weight of the encapsulant.

It is preferable that the encapsulant is an EVA material.

According to another aspect of the present invention, there is provided a PID-free photovoltaic module including: one or more solar cells; an encapsulant for packaging the one or more solar cells; a protective glass plate positioned on an upper surface of the encapsulant; a back sheet positioned on a lower surface of the encapsulant; and a frame, in which silica gel as a sodium ion adsorbent is dispersed in the encapsulant.

It is preferable that the surface area of the silica gel dispersed in the encapsulant is in a range of 500 m²/g to 800 m²/g and the silica gel is contained in an amount of 0.01 parts by weight to 1 part by weight based on 100 parts by weight of the encapsulant.

Preferably, the silica gel is dispersed only in the encapsulant positioned on the upper surface of the solar cell, and the encapsulant is made of EVA.

According to a further aspect of the present invention, there is provided a method of manufacturing a PID-free encapsulant sheet used to package a solar cell to form a photovoltaic module, the method including: preparing a composition of an encapsulant; and forming an encapsulant sheet by molding the composition of the encapsulant, in which in the preparing of the composition of the encapsulant, silica gel is added as a sodium ion adsorbent.

Preferably, the surface area of the silica gel dispersed in the encapsulate sheet is in a range of 500 m²/g to 800 m²/g and the silica gel is contained in an amount of 0.01 parts by weight to 1 part by weight based on 100 parts by weight of the encapsulant sheet.

Preferably, the silica gel is dispersed only in the encapsulant sheet disposed on an upper surface of the solar cell and the encapsulant sheet is made of EVA.

According to a yet further aspect of the present invention, there is provided a method of manufacturing a photovoltaic module including one or more solar cells, an encapsulant for packaging the one or more solar cells, a protective glass plate positioned on an upper surface of the encapsulant, a back sheet positioned on a lower surface of the encapsulant, and a frame.

When packaging the one or more solar cells with the encapsulant, encapsulant sheets are respectively placed on an upper surface and a lower surface of each of the one or more solar cells and are then thermally fused to seal the one or more solar cells, in which silica gel serving as a sodium ion adsorbent is dispersed in the encapsulant sheets.

Preferably, the surface area of the silica gel contained in the encapsulant sheet is in a range of 500 m²/g to 800 m²/g, and the silica gel is contained in the encapsulant sheet in an amount of 0.01 parts by weight to 1 part by weight based on 100 parts by weight of the encapsulant sheet.

Preferably, the encapsulant sheet is made of EVA.

According to the present invention configured as described above, since highly transparent silica gel is used as a sodium ion adsorbent, it is possible to prevent PID caused by sodium ions without preventing sunlight from being incident on solar cells, thereby preventing reduction in photovoltaic efficiency of a photovoltaic module.

In addition, since silica gel is a material having a high specific surface area, even a small amount of silica gel can sufficiently adsorb sodium ions, thereby preventing PID.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a cross-sectional view schematically illustrating a photovoltaic module;

FIGS. 2A and 2B are diagrams illustrating PID suppression efficiency of an encapsulant according to Example 1 and PID suppression efficiency of an encapsulant according to Comparative Example 1, respectively; and

FIGS. 3A and 3B are diagrams illustrating packaging films including the encapsulant according to Example 1 and the encapsulant according to Comparative Example 1, respectively.

### DESCRIPTION OF THE PREFERRED EMBODIMENTS

Hereinafter, embodiments of the present invention will be described in detail with reference to the accompanying drawings.

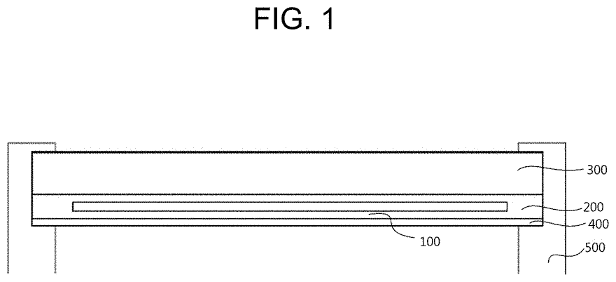

FIG. 1 is a schematic diagram illustrating a cross section of a photovoltaic module.

Referring to FIG. 1, a photovoltaic module includes an encapsulant 200 surrounding a solar cell 100, a protective glass plate 300 positioned on an upper surface of the encapsulant 200, a back sheet 400 positioned on a lower surface of the encapsulant 200, and a frame 500 for securing the assembled structure of these elements.

The solar cell 100 is not a single solar cell. It contains a plurality of solar cells which are electrically connected to each other and each of which is connected to a conductive wire that transfers electric charges from the corresponding solar cell to outside. However, the conductive wires, etc. are not illustrated in FIG. 1 for simplification of illustration.

The frame 500 of the photovoltaic module 100 is grounded and a potential difference occurs between the frame 500 and the solar cell 100. The protective glass plate 300 contains sodium as in common glass.

In a conventional photovoltaic module, sodium ions easily diffuse into the encapsulant 200 due to the potential difference between the solar cell 100 and the frame 500. In this case, due to the sodium ions in the encapsulant 200, the physical characteristics of the encapsulant 200 change. The sodium ions can easily move to and reach the surface of the solar cell 100, resulting in dielectric breakdown of an insulating film of the solar cell 100. Consequently, the overall performance degradation of the photovoltaic module occurs.

In order to solve this problem, according to the present invention, the encapsulant 200 is designed to contain silica gel on which metal ions including sodium ions can be adsorbed. Therefore, it is possible to suppress the movement of sodium ions released from the protective glass plate 300, thereby preventing PID-induced deterioration in the performance of the photovoltaic module. The surface of the silica gel has OH which will form hydrogen bonds with metal ions, thereby adsorbing the metal ions. Thus, the metal ions are immobilized on the surface of the silica gel.

Since the silica gel is highly transparent, the silica gel used in the present invention can prevent a problem in that the light incident on the solar cell 100 is reduced. As illustrated in FIG. 1, since sodium ions causing PID are released from the protective glass plate 300 positioned on the upper surface of the solar cell 100 on which sunlight is incident, it is preferable that an adsorbent material for adsorbing the sodium ions is dispersed in the encapsulant 200 positioned on the upper surface of the solar cell 100. That is, the adsorbent is disposed in the incident path along which the sunlight is incident on the solar cell 100. Sodium ion adsorbents, which have been proposed in the past, have low transparency. When the sodium ion adsorbents having low transparency are disposed in the incident path for sunlight, the photovoltaic efficiency of the photovoltaic module is deteriorated.

In the present invention, since silica gel that is a highly transparent material is used as a sodium ion adsorbent, a decrease in the photovoltaic efficiency of the photovoltaic module is not significant when the silica gel is dispersed in the incident path for sunlight.

Furthermore, since silica gel is a material with a high surface area, it is possible to adsorb a large number of metal ions even with a small amount of silica gel. That is, the amount of silica gel added to the encapsulant is relatively small in comparison with conventional adsorbents. Therefore, the large surface area of silica gel provides an advantage of reducing the deterioration in the photovoltaic efficiency of the photovoltaic module when silica gel is dispersed in the incident path for sunlight. In addition, the smaller the size of the particles of silica gel, the larger the overall specific surface area of silica gel. That is, as the size of the particles of the added silica gel decreases, the metal ion adsorption efficiency increases and the influence on the photovoltaic efficiency is reduced. Therefore, when silica gel powder is added to prepare the encapsulant according to the present invention, it is preferable to use silica gel having a small particle size. The appropriate particle size of the silica gel power may be selected in consideration of the cost. On the other hand, in the case of adding water-based silica sol or organic matter-based silica sol during preparation of an encapsulant, dispersibility of silica gel can be improved. In this case, since the specific surface area is an important factor, it is preferable to select silica having an appropriate particle size and having many pores on the surface.

According to one test example, the transmittance of an encapsulant (Example 1) prepared using a manufacturing method according to the present invention was measured. The test results showed that the transmittance of the encapsulant (Example 1) was 95% with respect to the transmittance of a conventional encapsulant (Comparative Example 1). The test results also showed that it was possible to improve the dispersibility of silica gel by mixing water-based silica sol or organic matter-based silica sol with the silica gel during preparation of the encapsulant (Example 1). In a case where the dispersibility of silica gel is improved, the sodium ion adsorption rate of the encapsulant is improved and thus the PID phenomenon is suppressed (refer to Test Example 1).

According to another test example, the PID suppression efficiency of the encapsulant (Example 1) prepared using the manufacturing method of the present invention was measured. The encapsulant prepared through the manufacturing method of the present invention exhibited improved PID suppression efficiency in comparison with the conventional encapsulant (Comparative Example 1) in which no silica gel is dispersed. The test results suggest that the present invention can reduce sodium-induced damage to an encapsulant and can reduce a decrease in the overall photovoltaic performance of a photovoltaic module because silica gel dispersed in the encapsulant according to the present invention effectively adsorbs sodium ions (refer to Test Example 2).

On the other hand, ethylene vinyl acetate (EVA) that is widely used in photovoltaic modules is used as a base material of the encapsulant 200. In the present invention, the encapsulant 200, specifically, silica gel in the encapsulant adsorbs sodium ions so that the sodium ions cannot reach the solar cells provided in a photovoltaic module.

The EVA-based encapsulant 200 contains conventional material applied to general photovoltaic modules without limitation. When manufacturing a photovoltaic module, EVA sheets having a larger size than a solar cell 100 are respectively placed on the upper surface and the lower surface of the solar cell 100 and then thermally fused to seal the solar cell 100. Through this process, the EVA sheets are bonded to the surfaces of the solar cell 100 so that the solar cell 100 can be sealed. Therefore, according to another aspect of the present invention, there is provided an EVA sheet that is prepared by adding silica gel serving as an adsorbent for metal ions to EVA during manufacturing of the EVA sheet.

A method of manufacturing a photovoltaic module according to another embodiment of the present invention features that a solar cell 100 is packaged with EVA sheets in which silica gel is contained as an adsorbent for metal ions. Alternatively, the EVA sheet in which silica gel is contained may be provided on only the upper surface of the solar cell to prevent sodium ions from diffusing into the solar cell and a general EVA sheet in which no silica gel is contained is provided on the lower surface of the solar cell.

The effect of immobilizing sodium ions in a manner that silica gel contained in the EVA sheet adsorbs the sodium ions depends on the surface area of the silica gel. Through the tests, it was found that the silica gel adsorbed about 0.7 sodium ions per a surface area of 1 nm² through hydrogen bonding. Accordingly, in order to prevent the PID phenomenon by adsorbing metal ions, the total surface area of the silica gel contained in the EVA sheet needs to be in a range of 500 m²/g to 800 m²/g. To this end, it is preferable that the silica gel is contained in an amount of 0.01 parts by weight to 1 part by weight based on 100 parts by weight of the EVA sheet.

As described above, an index that is directly related to a sodium ion adsorption effect is the surface area of silica gel. In order to obtain sufficient surface area for adsorbing metal ions based on the surface area of the porous silica gel in the range of 500 m²/g to 800 m²/g, 0.01 to 1 part by weight of silica gel needs to be dispersed in the EVA sheet. As the particle size of silica gel powder decreases, the total surface area of the silica gel powder per unit weight increases. Therefore, in the case of using silica gel powder having a relatively small particle size, a relatively small amount of silica gel may be used to obtain a sufficient surface area. However, since silica gel having a relatively small particle size is expensive, the cost of raw material increases when silica gel having a relatively small particle size is used.

### Example 1: Method of Manufacturing Encapsulant in which Silica Gel is Dispersed

Ethylene-vinyl acetate (EVA) copolymer or polyolefin elastomer (POE) was dissolved in toluene to prepare an encapsulant base material. Next, 0.05 parts by weight of silica gel and 0.05 parts by weight of water-based silica sol or organic matter-based silica sol serving as a dispersant were mixed with the base material. The resulting mixture was molded to form an encapsulant sheet. In this case, silica gel having a surface area of 650 m²/g was used.

### Comparative Example 1: Method of Manufacturing Encapsulant in which No Silica Gel is Dispersed

In this example, an encapsulant sheet was manufactured using the same method as in Example 1 except for silica gel and silica sol were not added to an encapsulant base material.

### Text Example 1: Observation of Dispersibility of Encapsulant

The dispersibility in Example 1 and the dispersibility in Comparative Example 1 were observed. The dispersibility was observed by measuring the transmittance of each of the encapsulant sheets as described below.

Specifically, samples having the same thickness were prepared according to Example 1 and Comparative Example 1 and compared in terms of the transmittance thereof with respect to 600 nm light by using a UV-spectrophotometer. The transmittance of the sample containing no silica particles was set to 1.00. The transmittance of the sample containing silica particles was represented as a ratio with respect to the transmittance of the sample containing no silica particles.

TABLE 1
Transmittance

| Example 1 | Comparative Example 1 |
|---|---|
| 0.97 | 1.00 |

As shown in Table 1, the transmittance of the encapsulant according to Example 1 was maintained at 95% or more relative to the transmittance of the encapsulant according to Comparative Example 1.

### Test Example 2: Observation of PID Suppression Effect of Encapsulant

The PID suppression effects of the encapsulants according to Example 1 and Comparative Example 1 were compared, and the results are shown in Table 2.

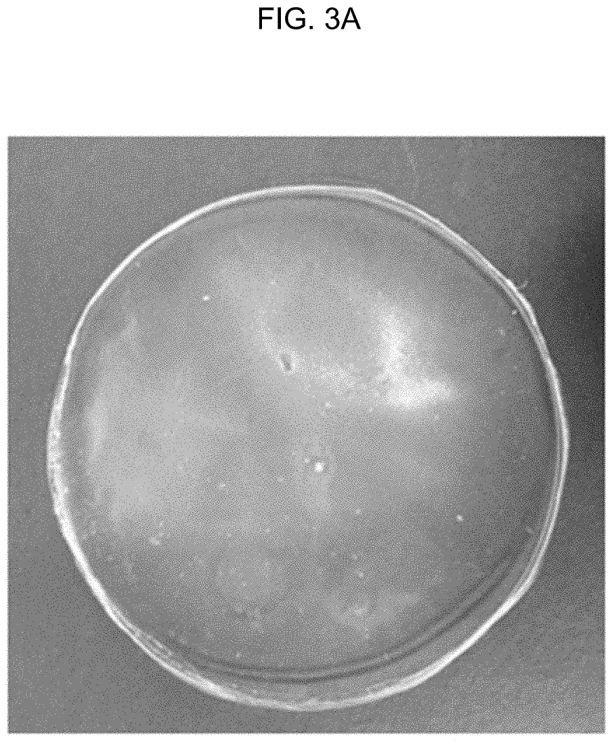

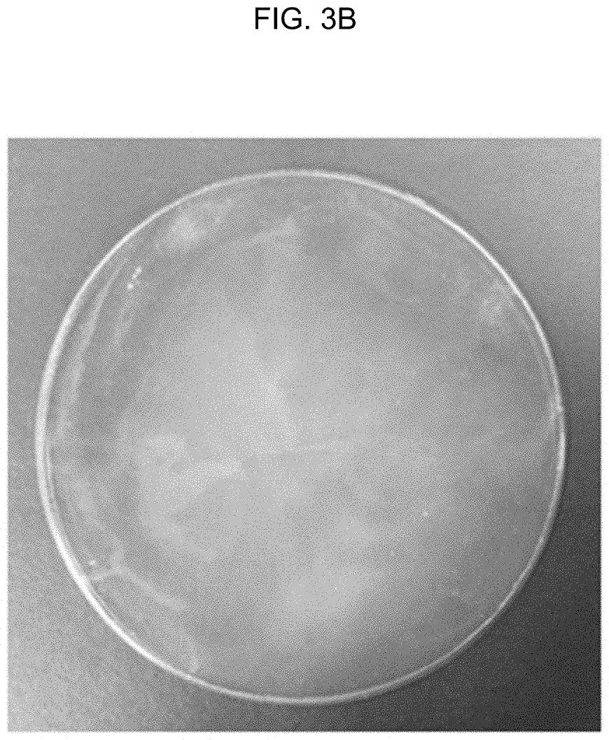

To this end, glass-to-glass photovoltaic modules were prepared by using crystalline silicon solar cells, a packaging film (see FIG. 3A) including the encapsulant according to Example 1, and a packaging film including the encapsulant according to Comparative Example 1. Next, a PID test was performed by applying an electric potential of 1000 V to each of the photovoltaic modules for 96 hours at a temperature of 83° C. and a humidity of 85% in compliance with a test standard of IEC 62804-1.

TABLE 2

| | Example 1 | | | | Comparative Example 1 | | | |
|---|---|---|---|---|---|---|---|---|
| | Eff | J_{sc} | Voc | FF | Eff | J_{sc} | Voc | FF |
| | (%) | (mA/cm²) | (V) | (%) | (%) | (mA/cm²) | (V) | (%) |
| Initial | 18.16 | 38.51 | 0.655 | 72.0 | 18.43 | 38.51 | 0.657 | 72.8 |
| After | 18.03 | 38.57 | 0.653 | 71.6 | 17.98 | 38.67 | 0.656 | 70.9 |
| PID | | | | | | | | |

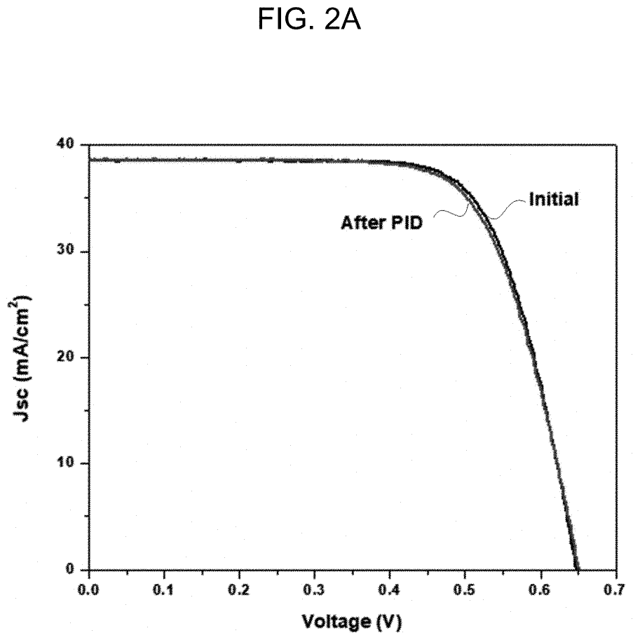

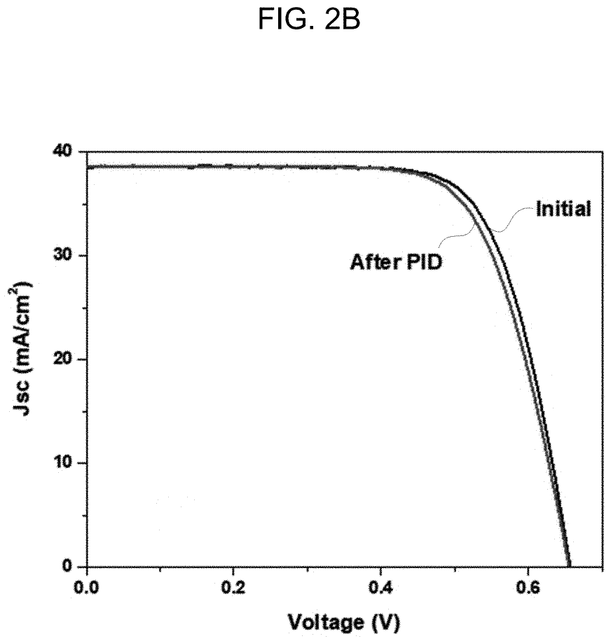

As shown in Table 2 and FIGS. 2A and 2B, the encapsulant according to Example 1 in which silica gel is dispersed exhibited an improved PID suppression effect in comparison with the encapsulant according to Comparative Example 1 in which silica gel is not contained.

### Test Example 3: Observation of Na Adsorption Performance of Encapsulant

The PID suppression effect of the encapsulant according to Example 1 was observed. Specifically, a weight ratio of EVA:silica gel was 100:1 and silica gel was added in an amount of 0.019 g. Since general silica gel has a specific surface area of 800 m²/g, the surface area of the added silica gel was 15.2 m² (i.e., 0.019×800=15.2 m²) when the photovoltaic (PV) modules were 1 m in length, 1 m in width, and 100 um in thickness.

That is, since it is known that 0.7 Na* ions can be adsorbed on the surface area of silica gel per 1 nm², a total of 10.6*10¹⁸ (i.e., 0.7*15.2*10¹⁸=10.6*10¹⁸) Na* ions can be adsorbed in a PV module of 1 m².

Accordingly, when the number of Na* ions is converted into the weight of Na, 0.4 mg of Na can be adsorbed (i.e., 23 (atomic weight)*1.06*10¹⁹/6.02*10²³=4.04*10⁻⁴ g).

While the present invention has been described with reference to the preferred embodiments, the above-described embodiments are merely illustrative of the technical idea of the present invention, and the ordinarily skilled in the art will appreciate that various changes or modifications to the embodiments can be made without departing from the technical idea of the present invention. Therefore, it is noted that the protection scope of the present invention should be interpreted not by the specific embodiments but by the matters recited in the claims, and all technical ideas equivalent to the matters recited in the claims should be interpreted as being included in the scope of the present invention.

What is claimed is:

1. An encapsulant for a photovoltaic module for preventing potential-induced degradation (PID), the encapsulant being used to seal a solar cell in the photovoltaic module, wherein silica gel is dispersed in the encapsulant as a sodium ion adsorbent.

2. The encapsulant according to claim 1, wherein the surface area of the silica gel dispersed in the encapsulant is in a range of 500 m²/g to 800 m²/g, and the amount of the silica gel dispersed in the encapsulant is 0.01 to 1 part by weight based on 100 parts by weight of the encapsulant.

3. The encapsulant according to claim 1, wherein the encapsulant is made of EVA.

4. A photovoltaic module for preventing potential-induced degradation (PID) comprising:
one or more solar cells;
an encapsulant surrounding the one or more solar cells;
a protective glass plate positioned on an upper surface of the encapsulant;
a back sheet positioned on a lower surface of the encapsulant; and
a frame,
wherein silica gel as a sodium ion adsorbent is dispersed in the encapsulant.

5. The photovoltaic module according to claim 4, wherein the surface area of the silica gel dispersed in the encapsulant is in a range of 500 m²/g to 800 m²/g, and the amount of the silica gel dispersed in the encapsulant is 0.01 to 1 part by weight based on 100 parts by weight of the encapsulant.

6. The photovoltaic module according to claim 4, wherein the silica gel is dispersed only in the encapsulant positioned on an upper surface of the solar cell.

7. The photovoltaic module according to claim 4, wherein the encapsulant is made of EVA.

8. A method of manufacturing an encapsulant sheet used to seal a solar cell in a photovoltaic module for preventing potential-induced degradation (PID), the method comprising:
preparing a composition of an encapsulant; and
molding the composition of the encapsulation to form the encapsulant sheet,
wherein in the preparing of the composition of the encapsulant, silica gel is added as a sodium ion adsorbent to the composition of the encapsulant.

9. The method according to claim 8, wherein the surface area of the silica gel is in a range of 500 m²/g to 800 m²/g, and the amount of the silica gel is 0.01 to 1 part by weight based on 100 parts by weight of the encapsulant.

10. The method according to claim 8, wherein the encapsulant is made of EVA.

11. The method according to claim 8, wherein the composition of the encapsulant includes water-based silica sol serving as a dispersant.

12. The method according to claim 8, wherein the composition of the encapsulant includes organic matter-based silica sol serving as a dispersant.
